(19) United States
(12) Patent Application Publication
(10) Pub. No.: US 2014/0177137 A1
(43) Pub. Date: Jun. 26, 2014

(54) TOUCH PANEL

(71) Applicant: AVCT OPTICAL ELECTRONIC CO., LTD, CHUNG LI (TW)

(72) Inventors: TING-CHING KUO, CHUNG LI (TW); JYR-DWO LEE, CHUNG LI (TW); SHIH-LIANG CHOU, CHUNG LI (TW); CHUN-JUNG HUANG, CHUNG LI (TW); HSUEH- CHIH CHIANG, CHUNG LI (TW)

(73) Assignee: AVCT OPTICAL ELECTRONIC CO., LTD, CHUNG LI (TW)

(21) Appl. No.: 13/723,317

(22) Filed: Dec. 21, 2012

(51) Int. Cl. H05K 7/02

(52) U.S. Cl. CPC H05K 7/02
USPC 361/679.01

(57) ABSTRACT

The invention relates to a touch panel. The touch panel includes a first transparent substrate, and an upper sensing pattern, upper metallic wires, a lower sensing pattern, lower metallic wires and a shielding member, all disposed on the first transparent substrate. Both of the upper and lower metallic wires are disposed around an outer periphery of the visual region—the wiring region. The shielding member is arranged between to the upper metallic wires and the lower metallic wires, so that the upper metallic wires and the lower metallic wires can be arranged in a manner overlapping with each other without causing interference between the wires. The invented touch panel has a reduced wiring area, in which the wiring region is minimized.

### BACKGROUND OF THE INVENTION

1. Field of the Invention

The present invention relates to a touch panel and, more particularly, to a touch panel having a reduced wiring area, in which the wiring region of the touch panel is much narrower as compared with the conventional touch panels.

2. Description of the Prior Art: In recent years, touch-sensing human-machine interface devices, such as touch panels, have been widely used in a broad variety of electrical and electronic devices, including global positioning system (GPS) devices, personal digital assistants (PDAs), cellular phones, and Hand-held PCs, in place of traditional input devices (such as a keyboard or a computer mouse). This structural innovation not only improves the communication between human and machine, but saves space by eliminating traditional input devices. As a result, the saved space can be utilized for accommodating a display panel which in turn provides the user a pleasant experience on displaying image data.

FIGS. 1(A) and (B) are perspective views of the conventional touch-sensing circuits. As illustrated, a conventional touch-sensing device 1 primarily includes sensing electrodes 12 and peripheral wires 13. The region on which the sensing electrodes 12 reside is responsible for detecting the user's touch operation and is defined herein as a touch-sensing region. The region on which the peripheral wires 13 are located is defined as a wiring region. The peripheral wires 13 electrically connect the sensing electrodes 12 to external detection circuits (not shown).

When a finger (or other electrically conductive objects) touches the touch-sensing device 1, the touch causes a capacitance change among the sensing electrodes 12. The capacitance change is then transmitted to the external detection circuits via the peripheral wires 13 and the external detection circuits determine the location of the finger touch by sensing the capacitance change.

With the rapid development of the fabrication technology for display panels and the increasing need for large-size display screens, the current designs for display panels tend to have narrower borders as compared to the display panels produced before. As a consequence, the layout design for the peripheral wires becomes extremely challenging due to a significant decrease in the border widths of display panels. Some of the conventional approaches to address the layout design are summarized below:

1. Narrower wire widths are used to reduce the wiring area. This approach, however, may increase the wire resistance, causing an increase in voltage drop across the wires and an interference with signal transmission. Moreover, it is difficult and cost-ineffective to produce display panels with narrower wires and this approach would easily reduce the production yield.

2. The peripheral wires are overlapped on the transparent conductive substrate, thereby reducing the wiring area. However, this approach may increase the risks of causing interference and short-circuit between the peripheral wires.

Therefore, there is a need for a better layout architecture compared to the conventional approaches, in which the peripheral wires are readily disposed within a narrow border region without causing interference between the wires.

### SUMMARY OF THE INVENTION

An object of the invention is to provide a touch panel having a reduced wiring area, in which the wiring region of the touch panel is much narrower as compared with the conventional touch panels.

In order to achieve the object described above, the touch panel according to the invention comprises a first transparent substrate, and an upper sensing pattern, a plurality of upper metallic wires, a lower sensing pattern, a plurality of lower metallic wires and a shielding member, all disposed on the first transparent substrate. The shielding member is arranged between the upper metallic wires and the lower metallic wires.

By virtue of the structural arrangement described above, the upper metallic wires and the lower metallic wires can be arranged in a manner overlapping with each other without causing interference between the wires. The invented touch panel has a reduced wiring area, in which the wiring region is minimized. The invented touch panel is also advantageous in preventing misreading of touch signals due to an unintentional direct contact between the wiring region with human body.

### BRIEF DESCRIPTION OF THE DRAWINGS

The above and other objects, features and effects of the invention will become apparent with reference to the following description of the preferred embodiments taken in conjunction with the accompanying drawing, in which:

FIGS. 1(A) and (B) are perspective views of the conventional touch-sensing circuits;

FIGS. 2(A) and (B) are schematic diagram illustrating the structure of the touch panel according to the invention;

FIG. 3 is a schematic cross-sectional view of the touch panel according to the first preferred embodiment of the invention;

FIG. 4 is a schematic cross-sectional view of the touch panel according to the second preferred embodiment of the invention;

FIG. 5 is a schematic cross-sectional view of the touch panel according to the third preferred embodiment of the invention;

FIG. 6 is a schematic cross-sectional view of the touch panel according to the fourth preferred embodiment of the invention; and

FIG. 7 is a schematic cross-sectional view of the touch panel according to the fifth preferred embodiment of the invention.

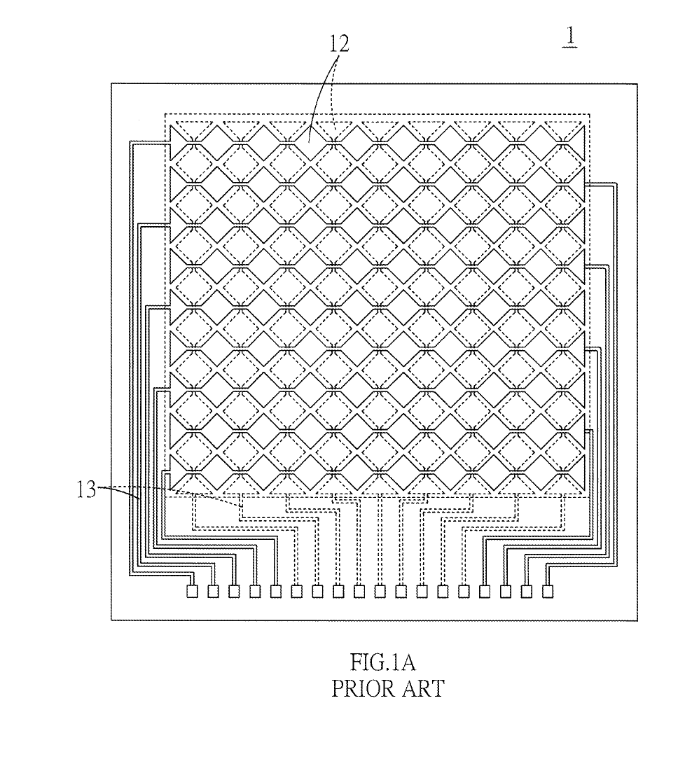

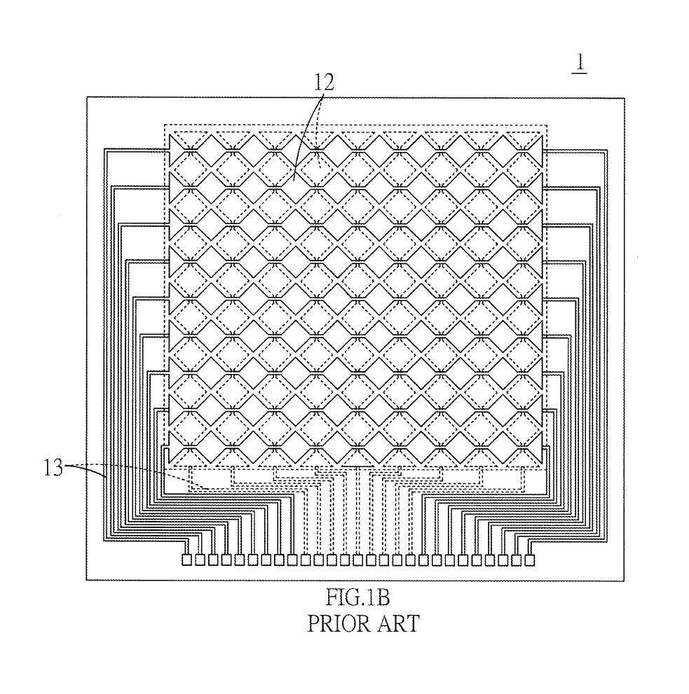

### DETAILED DESCRIPTION OF THE PREFERRED EMBODIMENTS

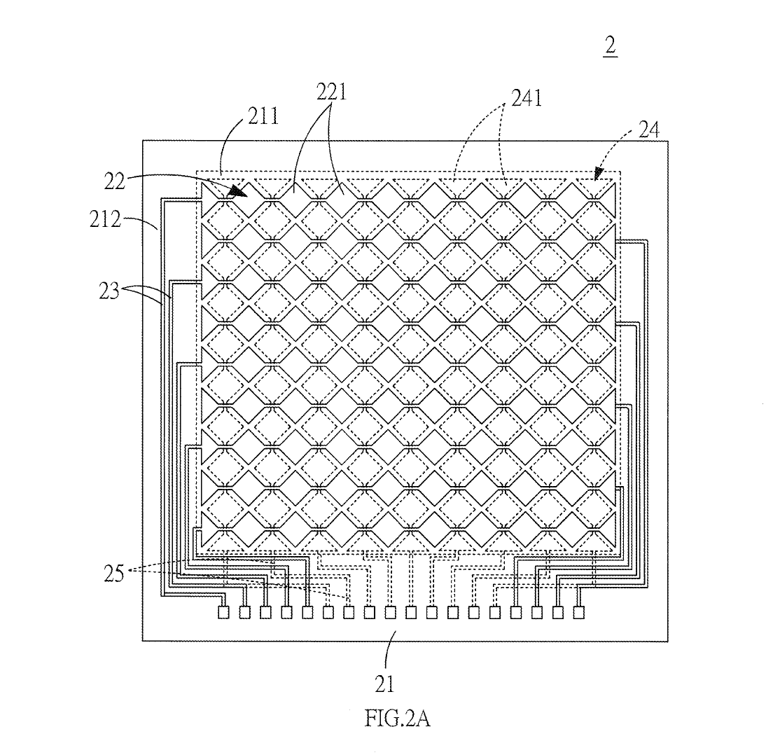

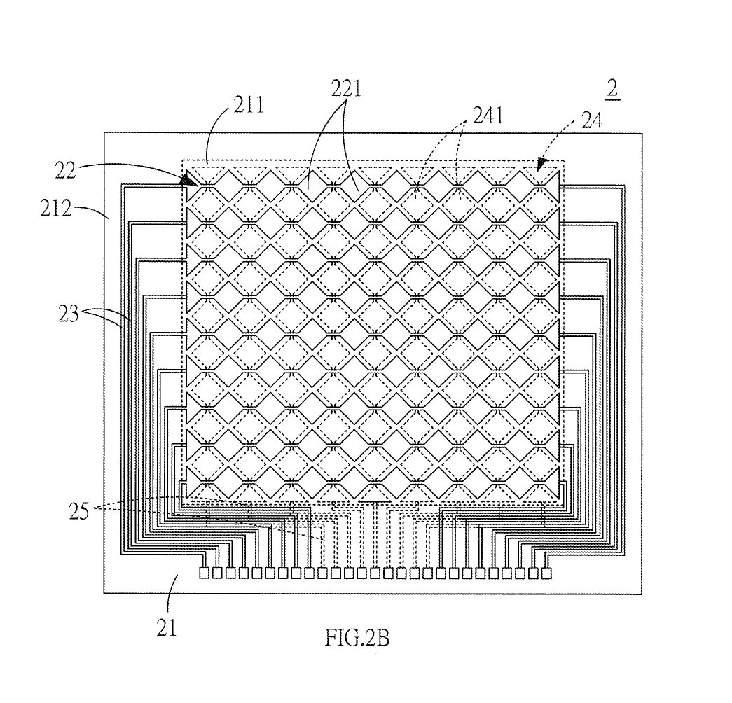

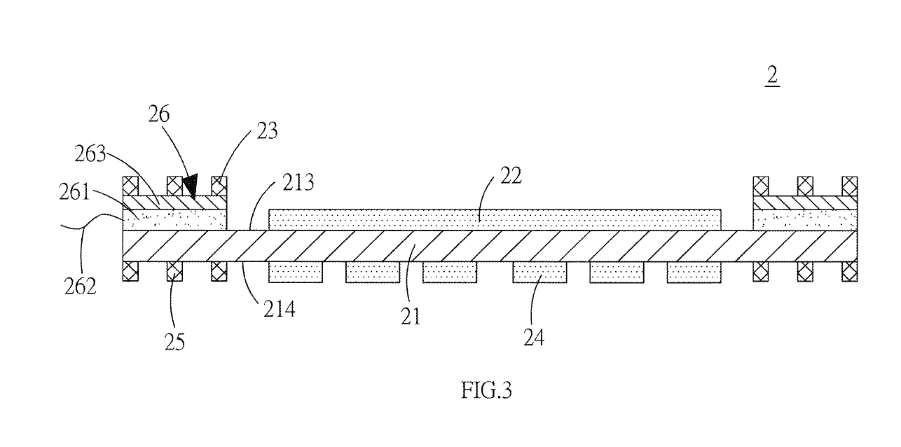

FIGS. 2(A) and (B) are schematic diagram illustrating the structure of the touch panel according to the invention, and FIG. 3 is a schematic cross-sectional diagram illustrating the touch panel according to the first preferred embodiment of the invention. As illustrated, the touch panel 2 disclosed herein comprises a first transparent substrate 21, an upper sensing pattern 22, a plurality of upper metallic wires 23, a lower sensing pattern 24, a plurality of lower metallic wires 25 and a shielding member 26.

The first transparent substrate 21 is formed with a visual region 211 and a wiring region 212 disposed around the outer periphery of the visual region 211. The first transparent substrate 21 includes an upper surface 213 and a lower surface 214 opposite to the upper surface 213.

The upper sensing pattern 22 comprises a plurality of upper sensing series 221 arranged in a first direction and resides in the visual region 211 of the first transparent substrate 21. According to the embodiment disclosed herein, the upper sensing pattern 22 is disposed on the upper surface 213 of the first transparent substrate 21.

The upper metallic wires 23 are disposed in the wiring region 212 of the first transparent substrate 21 and electrically connected to the upper sensing series 221 of the upper sensing pattern 22, respectively.

The lower sensing pattern 24 comprises a plurality of lower sensing series 241 arranged in a second direction and alternate to the upper sensing series 221 of the upper sensing pattern 22. The lower sensing pattern 24 is disposed in the visual region 211 and formed on the lower surface 214 of the first transparent substrate 21.

The lower metallic wires 25 are disposed in the wiring region 212 of the first transparent substrate 21 and electrically connected to the lower sensing series 241 of the lower sensing pattern 24. The lower metallic wires 25 are formed on the lower surface 214 of the first transparent substrate 21.

The shielding member 26 are disposed in the wiring region 212 and formed on the upper surface 213 of the first transparent substrate 21 and arranged between the upper metallic wires 23 and the lower metallic wires 25. The shielding member 26 comprises a conductive layer 261, a grounded wire 262 connected to the conductive layer 261, and an insulation layer 263 disposed on the conductive layer 261. The upper metallic wires 23 are disposed atop the insulation layer 263. In a more preferred embodiment, the conductive layer 261 is made of transparent conductive material and fabricated concurrently with the upper sensing pattern 22.

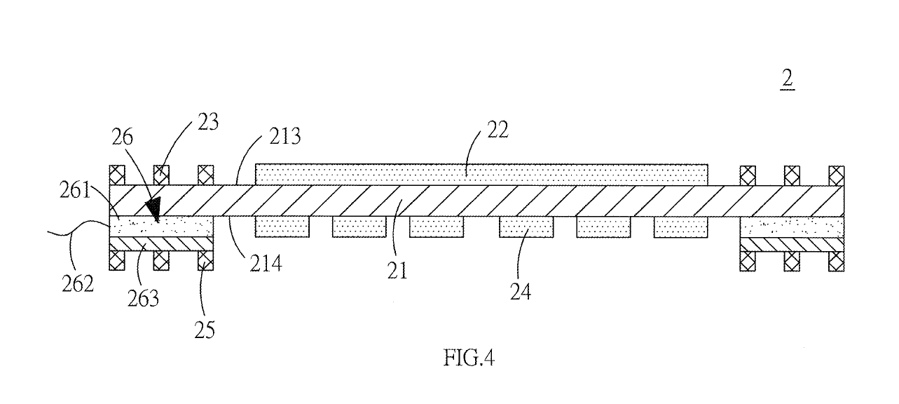

By virtue of mounting the shielding member 26 between the upper metallic wires 23 and the lower metallic wires 25, the upper metallic wires 23 and the lower metallic wires 25 can be arranged on the opposite sides of the first substrate 21 in a manner overlapping with each other, thereby preventing the occurrence of interference between the upper metallic wires 23 and the lower metallic wires 25. The invented touch panel 2 has a reduced wiring area, in which the wiring region 212 is minimized. The invented touch panel 2 is also advantageous in preventing misreading of touch signals due to an unintentional direct contact between the wiring region 212 with human body. According to the second preferred embodiment shown in FIG. 4, the upper sensing pattern 22 is disposed on the upper surface 213 of the first transparent substrate 21, and the lower sensing pattern 24 is disposed on the lower surface 214 of the first transparent substrate 21. The shielding member 26 is disposed on the lower surface 214 of the first transparent substrate 21, so that the lower metallic wires 25 are arranged beneath the insulation layer 263.

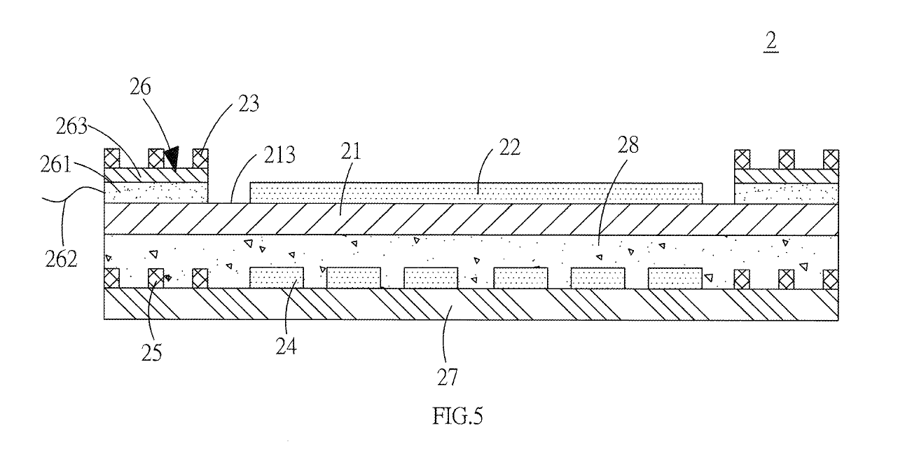

According to the third preferred embodiment shown in FIG. 5, the upper sensing pattern 22 is disposed on the upper surface 213 of the first transparent substrate 21, while a second transparent substrate 27 is attached via an optical adhesive 28 to the lower surface 214 of the first transparent substrate 21. The lower sensing pattern 24 is disposed on the second transparent substrate 27. The shielding member 26 is disposed on the upper surface 213 of the first transparent substrate 21, and the upper metallic wires 23 are arranged atop the insulation layer 263.

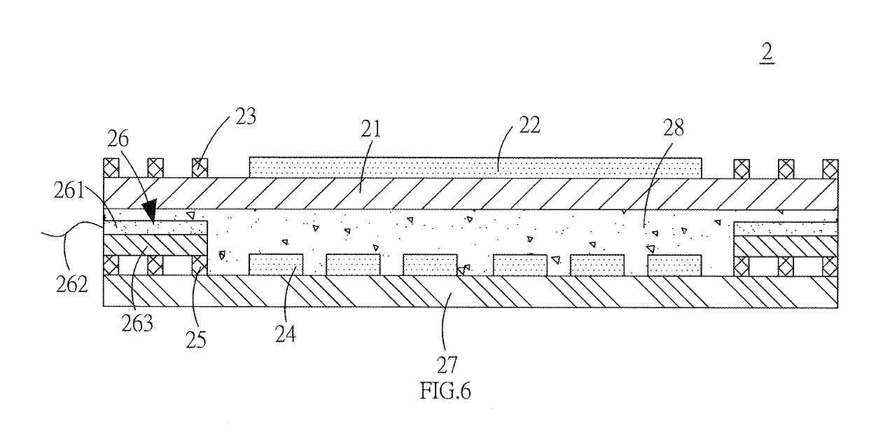

According to the fourth preferred embodiment shown in FIG. 6, the upper sensing pattern 22 is disposed on the upper surface 213 of the first transparent substrate 21, while a second transparent substrate 27 is attached via an optical adhesive 28 to the lower surface 214 of the first transparent substrate 21. The shielding member 26 is disposed on the lower surface 214 of the first transparent substrate 21, and the lower metallic wires 25 are arranged beneath the insulation layer 263.

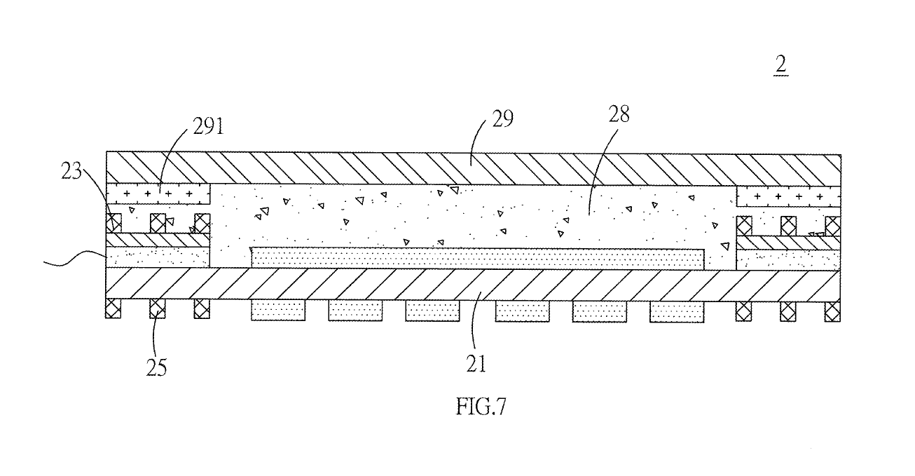

The first transparent substrate 21 is optionally coated with a protective layer 29, according to the fifth preferred embodiment shown in FIG. 7. The protective layer 29 may be coated on the first transparent substrate 21 via an optical adhesive 28. Optionally, a cover layer 291 is formed beneath the protective layer 29 in a manner facing the wiring region 212, so that the upper metallic wires 23 and the lower metallic wires 25 are both covered up by the cover layer 291 to improve the artistic appearance of the touch panel 2.

In conclusion, the touch panel disclosed herein can surely achieve the intended objects and effects of the invention by virtue of the structural arrangement described above. While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A touch panel comprising:
a first transparent substrate formed with a visual region and a wiring region disposed around an outer periphery of the visual region;
an upper sensing pattern disposed in the visual region of the first transparent substrate;
a plurality of upper metallic wires disposed in the wiring region of the first transparent substrate and connected to the upper sensing pattern;
a lower sensing pattern disposed in the visual region of the first transparent substrate and arranged alternate to the upper sensing pattern;
a plurality of lower metallic wires disposed in the wiring region of the first transparent substrate and connected to the lower sensing pattern; and
a shielding member disposed in the wiring region of the first transparent substrate and arranged between the upper metallic wires and the lower metallic wires, the shielding member comprising a conductive layer, a grounded wire connected to the conductive layer, and an insulation layer disposed on the conductive layer.

2. The touch panel according to claim 1, wherein the first transparent substrate comprises an upper surface and a lower surface opposite to the upper surface, and wherein the upper sensing pattern is disposed on the upper surface of the first transparent substrate, the lower sensing pattern is disposed on the lower surface of the first transparent substrate, the shielding member is disposed on the upper surface of the first transparent substrate and the upper metallic wires are disposed atop the insulation layer.

3. The touch panel according to claim 1, wherein the first transparent substrate comprises an upper surface and a lower surface opposite to the upper surface, and wherein the upper sensing pattern is disposed on the upper surface of the first transparent substrate, the lower sensing pattern is disposed on the lower surface of the first transparent substrate, the shielding member is disposed on the lower surface of the first transparent substrate and the lower metallic wires are disposed beneath the insulation layer.

4. The touch panel according to claim 1, wherein the first transparent substrate comprises an upper surface and a lower surface opposite to the upper surface, and wherein the upper sensing pattern is disposed on the upper surface of the first transparent substrate and a second transparent substrate is attached to the lower surface of the first transparent substrate, and wherein the lower sensing pattern is disposed on the second transparent substrate, the shielding member is disposed on the upper surface of the first transparent substrate, and the upper metallic wires are arranged atop the insulation layer.

5. The touch panel according to claim 4, wherein the second transparent substrate is attached via an optical adhesive to the first transparent substrate.

6. The touch panel according to claim 1, wherein the first transparent substrate comprises an upper surface and a lower surface opposite to the upper surface, and wherein the upper sensing pattern is disposed on the upper surface of the first transparent substrate and a second transparent substrate is attached to the lower surface of the first transparent substrate, and wherein the shielding member is disposed on the lower surface of the first transparent substrate and the lower metallic wires are arranged beneath the insulation layer.

7. The touch panel according to claim 6, wherein the second transparent substrate is attached via an optical adhesive to the first transparent substrate.

8. The touch panel according to claim 1, wherein the first transparent substrate is further coated with a protective layer.

9. The touch panel according to claim 8, wherein a cover layer is formed beneath the protective layer in a manner facing the wiring region.

10. The touch panel according to claim 8, wherein the protective layer is coated on the first transparent substrate via an optical adhesive.
